(19) United States
(12) Patent Application Publication
(10) Pub. No.: US 2006/0186943 A1
(43) Pub. Date: Aug. 24, 2006

(54) Ultra-low-power voltage transform circuit

(75) Inventors: Ja-nam Ku, Yongin-si (KR); Chung-woul Kim, Andong-si (KR); Young-hoon Min, Anyang-si (KR); Il-jong Song, Suwon-si (KR); Dong-hyun Lee, Seongnam-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/358,029

(22) Filed: Feb. 22, 2006

(30) Foreign Application Priority Data
Feb. 22, 2005 (KR) 2005-0014398

(51) Int. Cl. H03L 5/00

(52) U.S. Cl. 327/333

(57) ABSTRACT

A voltage transform circuit transforms a transferred voltage to a desired magnitude of voltage. The voltage transform circuit includes: a first power supply unit for providing a digital voltage (Vdd-1) of a first magnitude; a second power supply unit for providing an analog voltage (Vaa-2) of a second magnitude; and a voltage transform unit formed with a plurality of MOS transistors, wherein the MOS transistors operate to transfer the digital voltage (Vdd-1) from the first power supply unit, and output a digital voltage (Vdd-3) of a third magnitude corresponding to the analog voltage (Vaa-2) transferred from the second power supply unit. By using an analog voltage (Vaa-2) that is higher than the digital voltage (Vdd-1), it becomes possible to increase the magnitude of the output digital voltage (Vdd-3). By supplying this high digital voltage (Vdd-3) to a charge pump, the level of the charge pump is lowered.

### CROSS-REFERENCE TO RELATED APPLICATIONS

This application claims benefit under 35 U.S.C. § 119 from Korean Patent Application No. 2005-14398, filed on Feb. 22, 2005, the entire content of which is incorporated herein by reference.

### BACKGROUND OF THE INVENTION

1. Field of the Invention

Apparatuses and methods consistent with the present invention relates in general to an ultra-low-power voltage transform circuit, and more specifically, to a voltage transform circuit constituted by CMOS elements.

2. Description of the Related Art

In some cases, a system needs to transform an external low voltage to a higher voltage. That is, in the case where a voltage required for driving a specific configuration of a circuit element is higher than an externally supplied voltage, it is necessary to transform the externally supplied voltage into the required driving voltage. For instance, a minimum voltage of 15V is required for driving a memory, whereas an externally supplied voltage is typically 1.5V. Therefore, in order to drive the memory, the externally supplied voltage 1.5V should be transformed to 15V.

FIG. 1 illustrates a conventional voltage transform circuit for transforming an external low voltage to a higher voltage. The following description is based on this voltage transform circuit of FIG. 1.

As shown in the drawing, the voltage transform circuit includes Vᵢₙ receiving an externally supplied digital power, and Vₒᵤₜ for outputting the transformed power. Vᵢₙ and Vₒᵤₜ satisfy the relationship shown in Equation 1 below.

$$\frac{{V}_{out}}{{V}_{in}} = 2 \qquad [ Equation 1 ]$$

As shown in Equation 1, Vₒᵤₜ is dependent on Vᵢₙ. That is, if Vᵢₙ is small, Vₒᵤₜ is also small. Thus, if Vₒᵤₜ is used as an input voltage of a charge pump requiring a high voltage, the level of the charge pump is increased to transform Vₒᵤₜ to a required voltage. As a result, the circuit efficiency is lowered. Therefore, there is a need to develop a voltage transform circuit capable of transforming a supplied voltage to a desired voltage magnitude.

### SUMMARY OF THE INVENTION

Illustrative, non-limiting embodiments of the present invention overcome the above disadvantages and other disadvantages not described above. Also, the present invention is not required to overcome the disadvantages described above, and an illustrative, non-limiting embodiment of the present invention may not overcome any of the problems described above Apparatuses and methods consistent with the present invention provide a voltage transform circuit which is capable of transforming a supplied voltage to a desired voltage magnitude.

An aspect of an embodiment of the present invention is to provide a voltage transform circuit which is capable of increasing an input voltage to a charge pump, thereby improving the efficiency of the charge pump.

Another aspect of an embodiment of the present invention is to provide a method for lowering the level of a charge pump by increasing the magnitude of an voltage input to the charge pump.

In an illustrative, non-limiting embodiment of the present invention, there is provided a voltage transform circuit, including a first power supply unit for providing a digital voltage (Vdd-1) of a first magnitude, a second power supply unit for providing an analog voltage (Vaa-2) of a second magnitude, and a voltage transform unit formed with a plurality of MOS transistors, wherein an operation of each of the MOS transistors is controlled by transferring Vdd from the first power supply unit, and a digital voltage (Vdd-3) of a third magnitude correspondingly to Vaa transferred from the second power supply unit is output.

The magnitude of the digital voltage Vdd-1 is smaller than that of the analog voltage (Vaa-2).

The magnitude of the output digital voltage (Vdd-3) is greater than that of the analog voltage (Vaa-2).

The magnitude of the output digital voltage (Vdd-3) is twice the analog voltage (Vaa-2).

If the Vdd-1 is ‘high’, the output digital voltage (Vdd-3) is ‘high’; and if the Vdd-1 is ‘low’, the output digital voltage (Vdd-3) is ‘low’.

The voltage transform circuit comprises seven N-type MOS transistors, and seven P-type MOS transistors.

Another illustrative non-limiting embodiment of the present invention provides a voltage transform circuit, including a first power supply unit for providing a digital voltage (Vdd-1) of a first magnitude, a second power supply unit for providing an analog voltage (Vaa-2) of a second magnitude, a voltage transform unit formed with a plurality of MOS transistors, wherein an operation of each of the MOS transistors is controlled by transferring Vdd from the first power supply unit, and a digital voltage (Vdd-3) of a third magnitude correspondingly to Vaa transferred from the second power supply unit is output, and a charge pump for receiving the digital voltage (Vdd-3).

The magnitude of the digital voltage Vdd-1 is smaller than that of the analog voltage (Vaa-2).

The magnitude of the output digital voltage (Vdd-3) is greater than that of the analog voltage (Vaa-2).

The magnitude of the output digital voltage (Vdd-3) is twice the analog voltage (Vaa-2).

If the Vdd-1 is ‘high’, the output digital voltage (Vdd-3) is ‘high’; and if the Vdd-1 is ‘low’, the output digital voltage (Vdd-3) is ‘low’.

The voltage transform circuit comprises seven N-type MOS transistors, and seven P-type MOS transistors.

The charge pump boosts the transferred voltage Vdd-3.

### BRIEF DESCRIPTION OF THE DRAWINGS

Aspects and features of the present invention will be more apparent by describing certain illustrative, non-limiting embodiments of the present invention with reference to the accompanying drawings, in which:

FIG. 1 is a circuit diagram for transforming a low input voltage to a high voltage, according to a related art circuit;

FIG. 2 illustrates an example of a Dickson charge-pump circuit;

FIG. 3 illustrates the operation of the Dickson charge-pump circuit;

FIG. 4 is a circuit diagram for transforming a low voltage to a high voltage, according to an embodiment of the present invention; and

FIG. 5 is a voltage chart illustrating an input voltage and an output voltage to and from a voltage transform circuit of an embodiment of the present invention.

### DETAILED DESCRIPTION OF EXEMPLARY EMBODIMENTS

An illustrative non-limiting embodiment of the present invention is described below with reference to the accompanying drawings.

In general, the voltage magnitude of an RF analog power supply used in an antenna for example is relatively higher than the voltage magnitude of an externally supplied digital power supply. The embodiments of the present invention described here provide methods for transforming a voltage (magnitude) using an analog power supply instead of a digital power supply. First, a charge pump is explained below. A charge pump is a circuit for temporarily supplying a voltage higher than a power supply voltage. Nowadays a semiconductor memory device tends to have a lower power level to reduce energy consumption. Especially, a flash memory device requires a charge pump generating a high voltage for use in erasing data and programs in the flash memory.

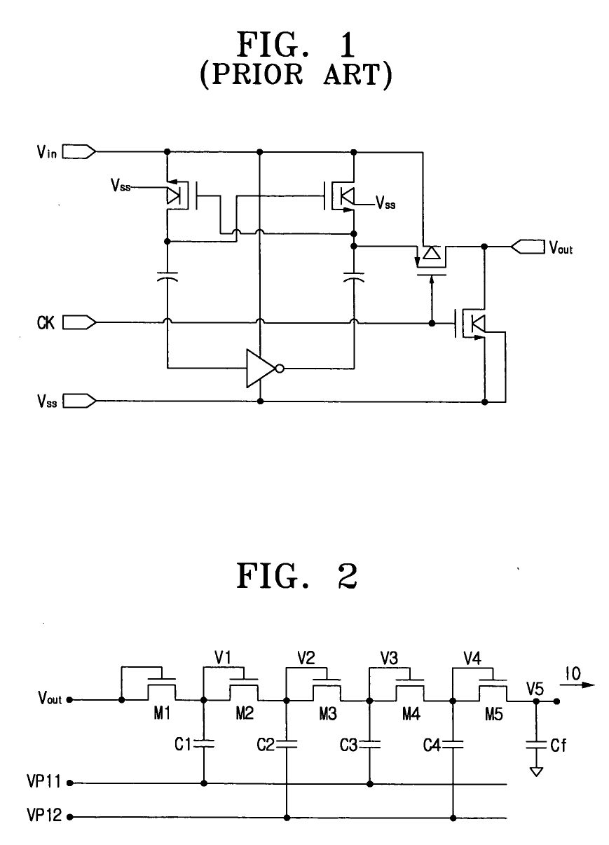

FIG. 2 illustrates the Dickson charge pump as an example of a charge pump.

The Dickson charge pump (circuit) includes a first MOS transistor M1 to which an external power supply voltage Vₒᵤₜ is applied, and second to fifth MOS transistors M2-M5 to which pumping clock pulses VP11, VP12 are applied. Pumping clock pulses VP11 and VP12 have different phases generated by an external oscillator (not shown) and are alternately applied through pump capacitors C1-C4. A charge storage capacitor Cf is connected to an output terminal of the fifth transistor M5.

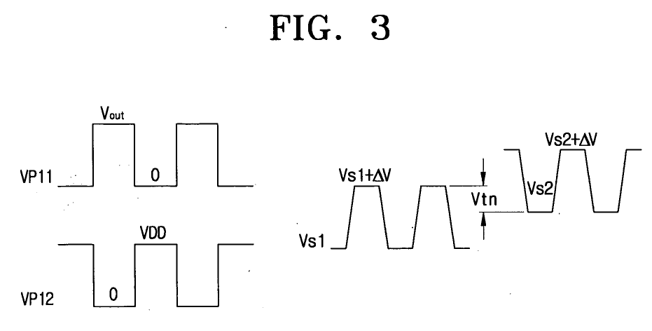

With reference to FIG. 3, the following describes the operation of the Dickson charge pump (circuit) shown in FIG. 2.

The pump clock pulses VP11, VP12, each having a frequency of about 60 MHz, are supplied from the external oscillator and are set to the same magnitude as the external power supply voltage Vₒᵤₜ. These pump clock pulses have a phase difference of 180° from each other. The MOS transistors M1-M5 function as diodes, hence, charge increases in only one direction.

Those two pump clock pulses VP11 and VP12 passing through the pump capacitors C1-C4, which are coupling capacitors, apply charge in a direction such that the charge increases through the MOS transistors M2-M5.

For instance, when the pump clock pulse VP11 transitions from ‘low’ to ‘high’, and the pump clock pulse VP12 transitions from ‘high’ to ‘low’, a voltage V1 applied to a gate side of the MOS transistor M2 is increased to Vs1+Δv as shown in FIG. 3 by the pumping operation of the pump clock pulse VP11 through the capacitor C1, and the voltage V2 applied to a gate side of the MOS transistor M3 is fixed at the value of Vs2.

The voltage Vs1 and the voltage Vs2 indicate a steady-state voltage of the voltage V1 and the voltage V2, respectively, and Δv indicates a very small voltage increment resulting from the pumping operation.

In this case, the MOS transistors M1, M3 are in a reverse bias state, and charge moves from the voltage V1 state to the voltage V2 state through MOS transistor M2. Here, the requirement for charge pumping is that Δv must be greater than a threshold voltage Vth of MOS transistor M2, as expressed below.
Δv>Vth [Equation 2]

A pumping gain Gv2 at the second level is defined as a difference between the voltage V1 and the voltage V2 as expressed below.
Gv2=V2−V1=Δv−Vth [Equation 3]

However, in Equation 3, the pumping gain is higher than the frequency of a clock, so the voltage V2 becomes smaller than an expected value.

In like manner, when the pump clock pulse VP11 transitions from ‘high’ to ‘low’, and the pump clock pulse VP12 transitions from ‘low’ to ‘high’, charge moves from the voltage V2 state to the voltage V3 state through MOS transistor M3.

The above-described operation is performed equally in the other MOS transistors M3-M5, so that the voltage V5 present at a final terminal is higher than the applied power supply voltage Vₒᵤₜ.

A desired voltage magnitude can be obtained by increasing the number of MOS transistors, or by increasing the magnitude of an applied power supply voltage. However, when the number of MOS transistors is increased, the efficiency of the charge pump (circuit), which consumes a large amount of current, is lowered. To overcome this drawback, a method is described here for increasing the magnitude of the power supply voltage applied to the charge pump (circuit).

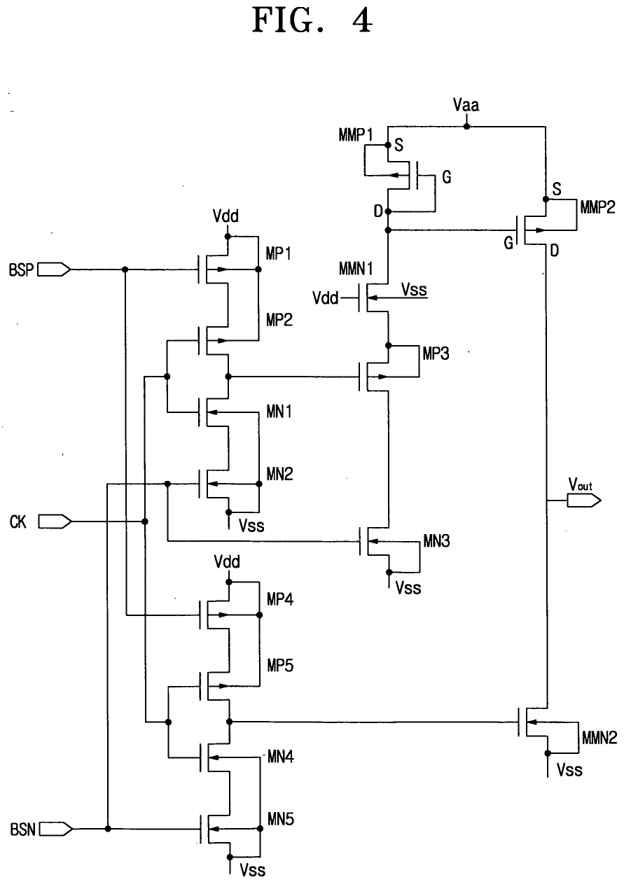

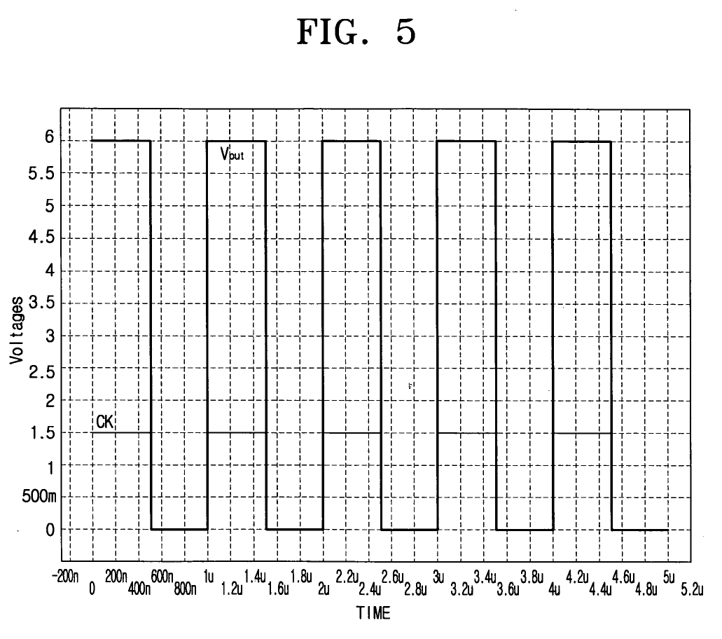

FIG. 4 is a circuit diagram illustrating a method for increasing the magnitude of a power supply voltage applied to the charge pump, in accordance with one embodiment of the present invention.

A voltage transform unit shown in FIG. 4 includes a plurality of CMOS transistors. The voltage transform unit receives power from an external power supply unit (not shown). That is, the external power supply unit provides the voltage transform unit with power signals BSP, CK, BSN, Vdd, Vss, Vaa, etc.

BSP provides power to the gates of MP1 and MP4, and BSN provides power to the gates of MN2 and MN5. BSP and BSN are current limiting bias terminals which limit a current flowing to the upper and lower input terminals of an inverter to realize an ultra low power of nA. In other words, MP2 and MN1 operate as one inverter, and the MP5 and the MN4 operate as one inverter. Thus, MP1, which receives power from BSP, limits a current transferring to the inverter realized by MP2 and MN1. Likewise, MP4, which receives power from BSP, limits a current transferring to the inverter realized by MP5 and MN4. Similarly, MN2, which receives power from BSN, limits a current transferring to the inverter realized by MP2 and MN1. Moreover, MN5, which receives power from BSN, limits a current transferring to the inverter realized by MP5 and MN4.

CK provides power to the upper and lower input terminals of the inverters to transform a low input voltage to a high voltage. When an input voltage to CK is ‘low’, an output voltage Vₒᵤₜ of MMN2 is also ‘low’. Also, when an input voltage to CK is ‘high’, the output voltage Vₒᵤₜ of MMN2 also is ‘high’. In this case, if an input voltage to CK is ‘high’, MP2 and MP5 are turned off, MMN2 is turned off and MMP2 is turned on. The magnitude of the output voltage Vₒᵤₜ becomes the drain voltage Vdd of MMP2. Vdd of MMP2 is a sum of a gate voltage and a source voltage Vaa at MMP2.

The gate voltage at MMP2 equals a drain voltage of MMP1 and the drain voltage of MMP1 is obtained by subtracting a voltage drop of a diode from the source voltage Vaa, i.e., ‘Vaa—voltage drop of diode’. Therefore, if the magnitude of the voltage drop of the diode is ignored, the drain voltage of MMP1 becomes Vaa, and Vₒᵤₜ equals to 2 Vaa.

FIG. 5 is a voltage chart showing a relationship between the CK signal and output voltage Vₒᵤₜ of the power supply voltage transform circuit of FIG. 4 according to an embodiment of the present invention. As shown in FIG. 5, when the magnitude of CK is 1.5V, the output voltage Vₒᵤₜ is 6V and the signals are in phase with one another. In the related art, when the magnitude of CK (Vdd) is 1.5V, the output voltage Vₒᵤₜ was 3V. However, here, the output voltage Vₒᵤₜ from the voltage transform circuit is 6V (=2 Vaa). In this manner, Vₒᵤₜ is made to depend on Vaa, instead of making Vₒᵤₜ depend on Vdd as in the related art. By using Vaa higher than Vdd, it becomes possible to increase the magnitude of a voltage applied to the charge pump, and reduce the level of the charge pump.

As explained so far, by using Vaa in addition to Vdd, the voltage transform circuit is able to transform a low input voltage to a high voltage. Since the output voltage from the voltage transform circuit of FIG. 4 is higher than that of the related art, the level of the charge pump can be reduced. This in turn reduces power consumption at the charge pump, and the efficiency of the charge pump can be improved.

The foregoing embodiment and advantages are merely exemplary and are not to be construed as limiting the present invention. The present teaching can be readily applied to other types of apparatuses. Also, the description of the embodiments of the present invention is intended to be illustrative, and not to limit the scope of the claims, and many alternatives, modifications, and variations will be apparent to those skilled in the art.

What is claimed is:

1. A voltage transform circuit, comprising:
a first power supply unit for providing a digital voltage (Vdd-1) of a first magnitude;
a second power supply unit for providing an analog voltage (Vaa-2) of a second magnitude; and
a voltage transform unit formed with a plurality of MOS transistors, wherein the MOS transistors operate to transfer the digital voltage (Vdd-1) from the first power supply unit, and output a digital voltage (Vdd-3) of a third magnitude corresponding to analog voltage (Vaa-2) transferred from the second power supply unit.

2. The voltage transform circuit according to claim 1, wherein the magnitude of the digital voltage Vdd-1 is smaller than the magnitude of the analog voltage (Vaa-2).

3. The voltage transform circuit according to claim 1, wherein the magnitude of the output digital voltage (Vdd-3) is greater than the magnitude of the analog voltage (Vaa-2).

4. The voltage transform circuit according to claim 3, wherein the magnitude of the output digital voltage (Vdd-3) is twice the magnitude of the analog voltage (Vaa-2).

5. The voltage transform circuit according to claim 1, wherein if the digital voltage (Vdd-1) is ‘high’, the output digital voltage (Vdd-3) is ‘high’; and if the digital voltage (Vdd-1) is ‘low’, the output digital voltage (Vdd-3) is ‘low’.

6. The voltage transform circuit according to claim 1, wherein the plurality of MOS transistors comprises seven N-type MOS transistors, and seven P-type MOS transistors.

7. A voltage transform circuit, comprising:
a first power supply unit for providing a digital voltage (Vdd-1) of a first magnitude;
a second power supply unit for providing an analog voltage (Vaa-2) of a second magnitude;
a voltage transform unit formed with a plurality of MOS transistors, wherein the MOS transistors operate to transfer the digital voltage (Vdd-1) from the first power supply unit, and output a digital voltage (Vdd-3) of a third magnitude corresponding to analog voltage (Vaa-2) transferred from the second power supply unit; and
a charge pump for receiving the output digital voltage (Vdd-3).

8. The voltage transform circuit according to claim 7, wherein the magnitude of the digital voltage (Vdd-1) is smaller than the magnitude of the analog voltage (Vaa-2).

9. The voltage transform circuit according to claim 7, wherein the magnitude of the output digital voltage (Vdd-3) is greater than the magnitude of the analog voltage (Vaa-2).

10. The voltage transform circuit according to claim 9, wherein the magnitude of the output digital voltage (Vdd-3) is twice the magnitude of the analog voltage (Vaa-2).

11. The voltage transform circuit according to claim 7, wherein if the digital voltage (Vdd-1) is ‘high’, the output digital voltage (Vdd-3) is ‘high’; and if the digital voltage (Vdd-1) is ‘low’, the output digital voltage (Vdd-3) is ‘low’.

12. The voltage transform circuit according to claim 7, wherein the plurality of MOS transistors comprises seven N-type MOS transistors, and seven P-type MOS transistors.

13. The voltage transform circuit according to claim 7, wherein the charge pump boosts the transferred digital voltage (Vdd-3).

14. A voltage transform circuit, comprising:
first and second inverters each having an input and an output, the inputs connected together, and each inverter powered by a first voltage signal;
means for generating an output voltage signal, said means being powered by at least a second voltage signal and controlled by the outputs of the first and second inverters, wherein the magnitude of said output voltage signal is greater than the magnitude of the second voltage signal.

15. The voltage transform circuit of claim 14, wherein the first voltage signal is a digital voltage signal and the second voltage signal is an analog voltage signal.

16. The voltage transform circuit of claim 15, wherein the magnitude of the output voltage signal is twice the magnitude of the second voltage signal.

17. The voltage transform circuit of claim 16, wherein said means for generating the output voltage signal comprises a plurality of MOS transistors.

18. The voltage transform circuit of claim 17, wherein a control signal is applied to the input of the inverters and the output signal is in phase with the control signal.
